(19) United States
(12) Patent Application Publication
(10) Pub. No.: US 2014/0127446 A1
(43) Pub. Date: May 8, 2014

(54) AMORPHOUS CARBON AND ALUMINUM MEMBRANE

(71) Applicants: Brigham Young University, (US); Moxtek, Inc., (US)

(72) Inventors: Robert Davis, Provo, UT (US); Richard Vanfleet, Provo, UT (US); Lei Pei, Provo, UT (US); Mallorie Harker, Springville, UT (US); Steven D. Liddiard, Springville, UT (US); Jonathan Abbot, Saratoga Springs, UT (US)

(73) Assignees: Moxtek, Inc., Orem, UT (US); Brigham Young University, Provo, UT (US)

(21) Appl. No.: 13/855,575

(22) Filed: Apr. 2, 2013

Related U.S. Application Data
(60) Provisional application No. 61/663,173, filed on Jun. 22, 2012.
(60) Provisional application No. 61/655,764, filed on Jun. 5, 2012.

(51) Int. Cl. H04R 1/00; B81B 3/00; G01L 9/00

(52) U.S. Cl. CPC H04R 1/00; G01L 9/0072; B81B 3/0078
USPC 428/69; 73/724; 381/150; 428/408; 428/216

(57) ABSTRACT

A membrane including at least one aluminum layer and at least one amorphous carbon layer. At least one polymer layer may also be included. Aluminum layer(s) can provide improved gas impermeability to the membrane. Amorphous carbon layer(s) can provide corrosion resistance. Polymer layer(s) can provide improved structural strength.

### CLAIM OF PRIORITY

Priority is claimed to U.S. Provisional Patent Application Ser. Nos. 61/663,173, filed on Jun. 22, 2012; and 61/655,764, filed on Jun. 5, 2012; which are hereby incorporated herein by reference in their entirety.

### FIELD OF THE INVENTION

The present application is related generally to thin membranes.

### BACKGROUND

Membranes can be used for separation of two different volumes of gas, or gas and vacuum, such as micro electro mechanical systems (MEMS). It can be desirable to have a membrane that is strong and resistant to corrosion.

### SUMMARY

It has been recognized that it would be advantageous to have a strong membrane that is resistant to corrosion. The present invention is directed to a membrane that satisfies these needs.

In one embodiment, the membrane includes an aluminum layer disposed between a first amorphous carbon layer and a second amorphous carbon layer. In another embodiment, the membrane includes a stack of thin film layers including an aluminum layer, a polymer layer, and an amorphous carbon layer. The above embodiments can be hermetically sealed to an enclosure having a hollow center. The amorphous carbon layer can be disposed as the farthest layer away from the hollow center.

### BRIEF DESCRIPTION OF THE DRAWINGS

FIG. 1 is a schematic cross-sectional side view of a membrane, including three layers of material, in accordance with an embodiment of the present invention;

FIG. 2 is a schematic cross-sectional side view of a membrane, including an amorphous carbon layer 23, two aluminum layers 21a-b, and a polymer layer 22, in accordance with an embodiment of the present invention;

FIG. 3 is a schematic cross-sectional side view of a membrane, including two amorphous carbon layers 23a-b, two aluminum layers 21a-b, and a polymer layer 22, in accordance with an embodiment of the present invention;

FIG. 4 is a schematic cross-sectional side view of a membrane, including two amorphous carbon layers 23a-b, two aluminum layers 21a-b, and a polymer layer 22, in accordance with an embodiment of the present invention;

FIG. 5 is a schematic cross-sectional side view of a membrane, including an amorphous carbon layer 23 disposed between a polymer layer 22 and an aluminum layer 21, in accordance with an embodiment of the present invention;

FIG. 6 is a schematic cross-sectional side view of a membrane, including an aluminum layer 21 disposed between a polymer layer 22 and an amorphous carbon layer 23, in accordance with an embodiment of the present invention;

FIG. 7 is a schematic cross-sectional side view of a membrane, including an aluminum layer 21 disposed between two amorphous carbon layers 23a-b, in accordance with an embodiment of the present invention;

FIG. 8 is a schematic cross-sectional side view of a membrane 81, separated from a conducting layer 83 by electrically insulative separators 82, and forming a hollow center 85, that can be hermetically separated from surrounding gas 84, such as the atmosphere, in accordance with an embodiment of the present invention.

### DEFINITIONS

As used herein, the term amorphous carbon means an allotrope of carbon that lacks crystalline structure and includes both sp3 (tetrahedral or diamond-like) bonds and sp2 (trigonal or graphitic) bonds.
Hydrogenated amorphous carbon means an amorphous carbon in which some of the carbon atoms are bonded to hydrogen atoms.

### DETAILED DESCRIPTION

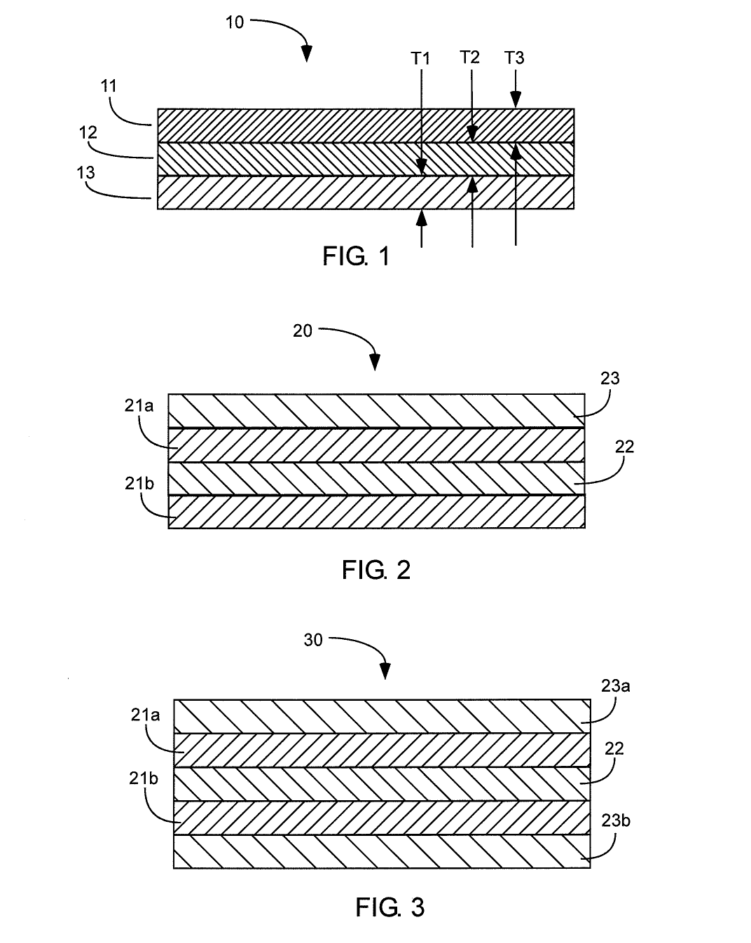

As illustrated in FIG. 1, a membrane 10 is shown comprising a stack of at least three layers 11-13 of material. The layers 11-13 can include at least one aluminum layer, at least one amorphous carbon layer, and/or at least one polymer layer. The layers can each have a thickness T1-3.

Use of polymer layer(s) can be beneficial for providing structural strength to the membrane. Aluminum layer(s) can provide improved gas impermeability to the membrane. Amorphous carbon layer(s) can provide corrosion resistance.

The aluminum layer(s) can be substantially pure aluminum, or can include other elements. A mass percent of aluminum in the aluminum layer(s) can be at least 80% in one embodiment, at least 95% in another embodiment, or at least 99% in another embodiment. In the various embodiments described herein, the aluminum layer(s) can have various thicknesses. For example, the aluminum layer(s) can have a thickness of between 10 to 30 nanometers in one embodiment, or a thickness of between 10 to 60 nanometers in another embodiment.

The amorphous carbon layer(s) can comprise only carbon, or substantially only carbon, in one embodiment. The amorphous carbon layer(s) can have various percentages of carbon. For example, a mass percent of carbon in the amorphous carbon layer(s) can be at least 80% in one embodiment, at least 95% in another embodiment, or at least 99% in another embodiment.

Hybridization of carbon in the amorphous carbon layer(s) can include both sp3 hybridization and sp2 hybridization in various relative percentages. For example, the percent sp3 hybridization can be between 5% and 25% in one embodiment, between 15% and 25% in another embodiment, between 5% and 15% in another embodiment, or less than 25% in another embodiment. The percent sp2 hybridization can be between 75% and 95% in one embodiment, between 85% and 95% in another embodiment, between 85% and 95% in another embodiment, or greater than 75% in another embodiment.

The amorphous carbon layer(s) can be hydrogenated amorphous carbon layer(s) in another embodiment. Hydrogen inside the amorphous carbon matrix can help to stabilize the sp3 carbon atoms and can improve the cohesiveness of the layer. There can be many different percentages of atomic percent of hydrogen in the hydrogenated amorphous carbon layer. For example, an atomic percent of hydrogen in the hydrogenated amorphous carbon layer can be between 50% and 70% in one embodiment, between 25% and 51% in another embodiment, between 14% and 26% in another embodiment, between 5% and 15% in another embodiment, between 1% and 10% in another embodiment, or between 0.1% and 2% in another embodiment.

The amorphous carbon layers can have various thicknesses. For example, the amorphous carbon layer(s), including hydrogenated amorphous carbon layer(s), can have a thickness of between 5 to 25 nanometers in one embodiment, or a thickness of between 1 to 25 nanometers in another embodiment.

The polymer layer(s) can have various mass percentages of polymer. For example, a mass percent of polymer in the polymer layer(s) can be at least 80% in one embodiment, at least 95% in another embodiment, or at least 99% in another embodiment. The term “mass percent of polymer” means percent by mass in the layer that are elements of the polymer selected, such as carbon and hydrogen, and possibly other elements, depending on the polymer selected. The polymer layer can consist of only polymer in one embodiment, or can include other elements or molecules in another embodiment.

The polymer layer(s) can have various thicknesses. For example, and the polymer layer can have a thickness of between 150 to 300 nanometers.

The polymer can be or can include a polyimide. Polyimide can be useful due to its high strength and high temperature resistance as compared with many other polymers.

As illustrated in FIG. 2, a membrane, 20 is shown comprising a stack of thin film layers including a first aluminum layer 21a, a second aluminum layer 21b, a polymer layer 22, and an amorphous carbon layer 23. An order of the stack of thin film layers is the amorphous carbon layer 23, the first aluminum layer 21a, the polymer layer 22, then the second aluminum layer 21b. In other words, the first aluminum layer 21a and the polymer layer 22 are disposed between the amorphous carbon layer 23 and the second aluminum layer 21b and the polymer layer 22 is disposed between the two aluminum layers 21a-b. The polymer layer 22 can provide structural support. The two aluminum layers 21a-b, which sandwich the polymer layer 22, can help provide gas impermeability. The amorphous carbon layer 23 can provide corrosion protection to the first aluminum layer 21a.

As illustrated in FIG. 3, a membrane, 30 is shown comprising a stack of thin film layers including a first aluminum layer 21a, a second aluminum layer 21b, a polymer layer 22, a first amorphous carbon layer 23a, and a second amorphous carbon layer 23b. An order of the stack of thin film layers is the first amorphous carbon layer 23a, the first aluminum layer 21a, the polymer layer 22, the second aluminum layer 21b, then the second amorphous carbon layer 23b. In other words, the polymer layer 22 is disposed between the two aluminum layers 21a-b. The polymer layer 22 and the two aluminum layers 21a-b are disposed between two amorphous carbon layers 23a-b. The polymer layer can 22 provide structural support. The two aluminum layers 21a-b, which sandwich the polymer layer 22, can help provide gas impermeability. The amorphous carbon layers 23a-b can provide corrosion protection to the aluminum layers 21a-b. Selection of membrane 20 of FIG. 2 or membrane 30 of FIG. 3 may be made based on whether there is a need for corrosion protection of both aluminum layers 21a-b, manufacturability, and cost considerations.

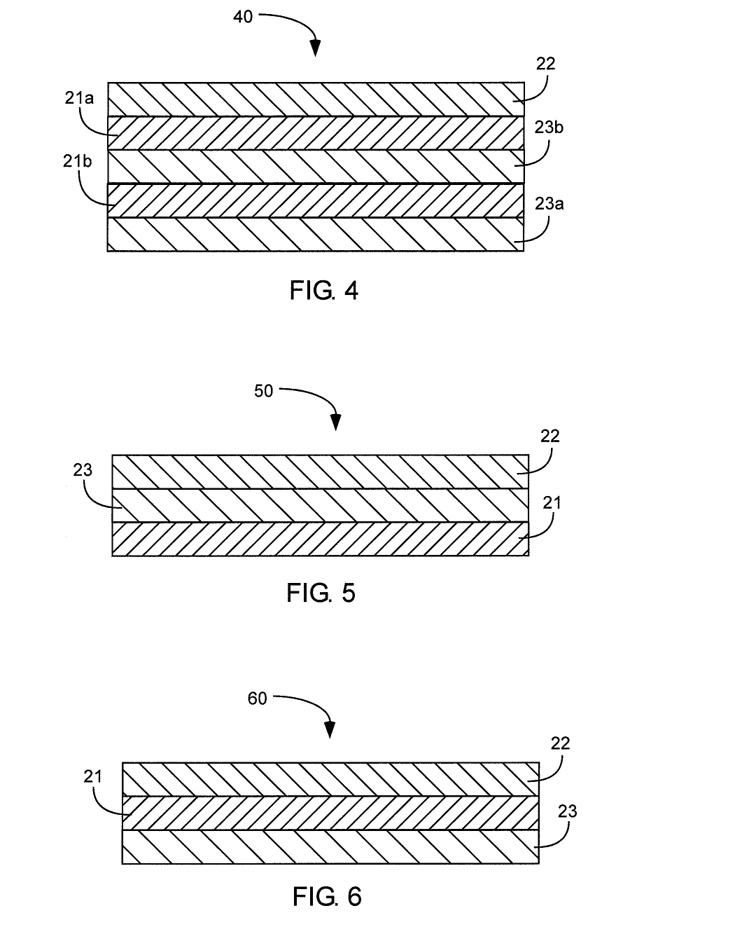

As illustrated in FIG. 4, a membrane, 40 is shown comprising a stack of thin film layers including a first aluminum layer 21a, a second aluminum layer 21b, a polymer layer 22, a first amorphous carbon layer 23a, and a second amorphous carbon layer 23b. An order of the stack of thin film layers is the polymer layer 22, the first aluminum layer 21a, the second amorphous carbon layer 23b, the second aluminum layer 21b, then first amorphous carbon layer 23a. In other words, the second amorphous carbon layer 23b is disposed between the two aluminum layers 21a-b. The second amorphous carbon layer 23b and the two aluminum layers 21a-b are disposed between the polymer layer 22 and the first amorphous carbon layer 23a. The polymer layer can 22 provide structural support. The two aluminum layers 21a-b can help provide gas impermeability. The amorphous carbon layers 23a-b can provide corrosion protection.

As illustrated in FIG. 5, a membrane, 50 is shown comprising a stack of thin film layers including an aluminum layer 21, a polymer layer 22, and an amorphous carbon layer 23. An order of the stack of thin film layers is the polymer layer 22, the first amorphous carbon layer 23, then the aluminum layer 21. In other words, the amorphous carbon layer 23 is disposed between the polymer layer 22 and the aluminum layer 21. This embodiment can be useful due to a small number of layers, thus allowing ease of manufacturing and reducing cost. The aluminum layer can be protected from corrosion if the aluminum layer is disposed to face a protected environment, such as the vacuum portion of the device for example, and the polymer layer disposed towards a more corrosive environment, such as the ambient air.

As illustrated in FIG. 6, a membrane, 60 is shown comprising a stack of thin film layers including an aluminum layer 21, a polymer layer 22, and an amorphous carbon layer 23. An order of the stack of thin film layers is the polymer layer 22, the aluminum layer 21, then the amorphous carbon layer 23. In other words, the aluminum layer 21 is disposed between the polymer layer 22 and the amorphous carbon layer 23. This embodiment can be useful due to a small number of layers, thus reducing cost and allowing ease of manufacturing. The aluminum layer 21 can improve gas impermeability of the polymer layer 22 and the amorphous carbon layer can provide corrosion protection to the aluminum layer 21.

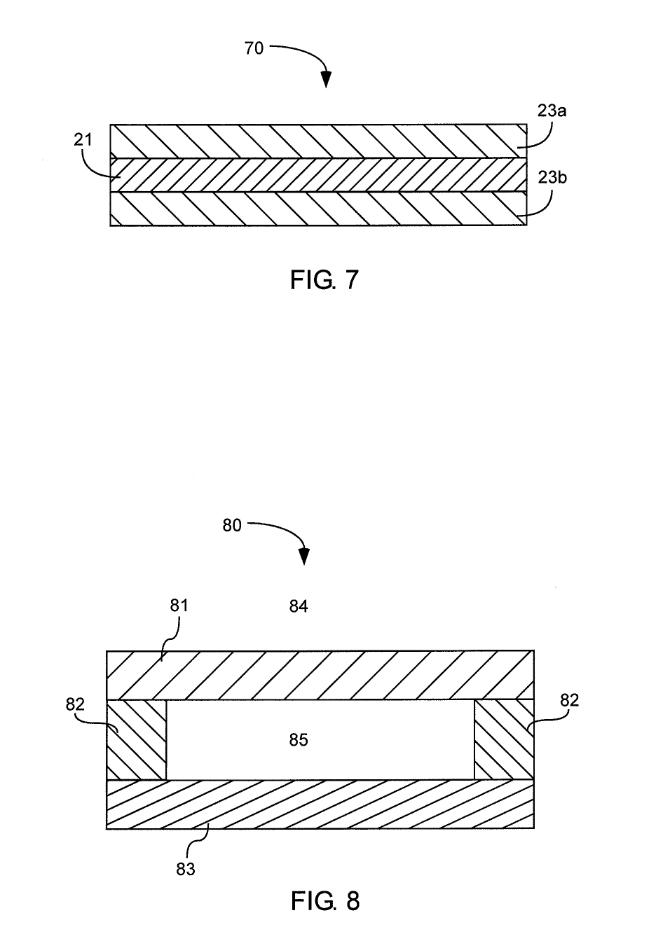

As illustrated in FIG. 7, a membrane, 70 is shown comprising a stack of thin film layers including an aluminum layer 21, a first amorphous carbon layer 23a, and a second amorphous carbon layer 23b. An order of the stack of thin film layers is the first amorphous carbon layer 23a, the aluminum layer 21, then the second amorphous carbon layer 23b. In other words, the aluminum layer 21 is disposed between the two amorphous carbon layers 23a-b. This embodiment can be useful due to a small number of layers, thus allowing ease of manufacturing and reducing cost. The aluminum layer can improve strength and gas impermeability. The amorphous carbon layers 23a-b can provide corrosion protection to the aluminum layer 21.

As illustrated in FIG. 8, a membrane 81 can be separated from an electrically conducting layer 83 by electrically insulative separators 82, thus forming a hollow center 85 that can be hermetically separated from surrounding gas 84, such as the atmosphere. The electrically conducting layer 83 can be metallic. The device 80 in FIG. 1 can be a micro electro mechanical system (MEMS).

The device 80 in FIG. 8 can be a speaker or a sound emitter. The membrane 81 can be electrically conductive. A voltage differential between the membrane 81 and the conducting layer 83 can change, causing the membrane to flex with the changes in the voltage differential, resulting in emission of sound.

The device 80 in FIG. 8 can be a capacitive pressure sensor. A pressure differential between the hollow center 85 and the surrounding gas 84 can change, causing the membrane to flex with the changes in the pressure differential. The flexing of the membrane can be sensed by changing capacitance between the membrane 81 and the conducting layer 83.

An alternative to amorphous carbon layer(s) is use of HMDS (hexamethyldisilazane) layer(s). HMDS is an organosilicon compound with the molecular formula [(CH3)3Si]2NH. Thus, amorphous carbon layer(s) may be replaced with HMDS layer(s) in any location in this document. Either amorphous carbon or HMDS can serve as a corrosion barrier. HMDS may be sputter deposited.

### How To Make:

The aluminum layer can be evaporation deposited. The aluminum layer and/or the amorphous carbon layer can be sputter deposited. Evaporation might be selected due to lower cost. Sputter might be selected due to improved ability to control film structure and adhesion.

Amorphous carbon layers have been successfully deposited by magnetron reactive gas sputtering with the following parameters and process:
DC Power: 400 watts
Target: graphite (99.999% purity)
Pump chamber pressure down to 2.3E-5 torr
Flow Ar gas to 7 mTorr
Turn DC Power up from 50W to 400W for 2 minutes
Flow ethylene at Ar:ethylene 9:1 ratio and dwell for 1 minute
Open shutter for deposition. Keep the substrate plate at about 30° C. with rotation.
Close shutter and ramp down power for 2 minutes
Vent the chamber

What is claimed is:

1. A micro electro mechanical system comprising:
a. a membrane separated from a conducting layer by electrically insulative separators, forming a hollow center that is hermetically separated from gas surrounding the system;
b. the membrane comprising a stack of thin film layers including an aluminum layer, a polymer layer, and an amorphous carbon layer.

2. The system of claim 1, wherein the system is a speaker or a capacitive pressure sensor.

3. A membrane device comprising a stack of thin film layers including an aluminum layer, a polymer layer, and an amorphous carbon layer.

4. The device of claim 3, wherein hybridization of carbon in the amorphous carbon layer is:
a. less than 25% sp3 hybridization; and
b. greater than 75% sp2 hybridization.

5. The device of claim 3, wherein the amorphous carbon layer is a hydrogenated amorphous carbon layer.

6. The device of claim 5, wherein an atomic percent of hydrogen in the hydrogenated amorphous carbon layer is between 1% and 10%.

7. The device of claim 3, wherein the polymer is a polyimide.

8. The device of claim 3, wherein:
a. a mass percent of aluminum in the aluminum layer is at least 95%;
b. a mass percent of polymer in the polymer layer is at least 95%;
c. a mass percent of carbon and hydrogen in the amorphous carbon layer is at least 95%.

9. The device of claim 3, wherein:
a. the amorphous carbon layer comprises a first amorphous carbon layer and a second amorphous carbon layer;
b. the aluminum layer comprises a first aluminum layer and a second aluminum layer; and
c. an order of the layers in the stack of thin film layers is the first amorphous carbon layer, the first aluminum layer, the polymer layer, the second aluminum layer, then the second amorphous carbon layer.

10. The device of claim 9, wherein:
a. the first amorphous carbon layer has a thickness of between 5 to 25 nanometers;
b. the first aluminum layer has a thickness of between 10 to 30 nanometers;
c. the polymer layer has a thickness of between 150 to 300 nanometers;
d. the second aluminum layer has a thickness of between 10 to 30 nanometers; and
e. the second amorphous carbon layer has a thickness of between 5 to 25 nanometers.

11. The device of claim 3, wherein:
a. the amorphous carbon layer comprises a first amorphous carbon layer and a second amorphous carbon layer;
b. the aluminum layer comprises a first aluminum layer and a second aluminum layer; and
c. an order of the layers in the stack of thin film layers is the polymer layer, the first aluminum layer, the first amorphous carbon layer, the second aluminum layer, then second amorphous carbon layer.

12. The device of claim 11, wherein:
a. the polymer layer has a thickness of between 150 to 300 nanometers;
b. the first aluminum layer has a thickness of between 10 to 30 nanometers;
c. the first amorphous carbon layer has a thickness of between 5 to 25 nanometers;
d. the second aluminum layer has a thickness of between 10 to 30 nanometers; and
e. the second amorphous carbon layer has a thickness of between 5 to 25 nanometers.

13. The device of claim 3, wherein an order of the layers in the stack of thin film layers is the polymer layer, the aluminum layer, then the amorphous carbon layer.

14. The device of claim 13, wherein:
a. the polymer layer has a thickness of between 150 to 300 nanometers;
b. the aluminum layer has a thickness of between 10 to 30 nanometers; and
c. the amorphous carbon layer has a thickness of between 5 to 25 nanometers.

15. The device of claim 3, wherein an order of the layers in the stack of thin film layers is the polymer layer, the amorphous carbon layer, then the aluminum layer.

16. The device of claim 15, wherein:
a. the polymer layer has a thickness of between 150 to 300 nanometers;
b. the amorphous carbon layer has a thickness of between 5 to 25 nanometers; and
c. the aluminum layer has a thickness of between 10 to 30 nanometers.

17. The device of claim 3, wherein:
a. the membrane is separated from a conducting layer by electrically insulative separators, forming a hollow center that is hermetically separated from gas surrounding the system;
b. the amorphous carbon layer is disposed as the farthest layer from the hollow center.

18. The device of claim 3, wherein:
a. the aluminum layer comprises a first aluminum layer and a second aluminum layer; and
b. an order of the stack of thin film layers is the first aluminum layer, the polymer layer, the second aluminum layer, then the amorphous carbon layer.

19. The device of claim 18, wherein:
a. The amorphous carbon layer is a hydrogenated amorphous carbon layer;
b. the polymer layer comprises polyimide (“polyimide layer”);
c. the polyimide layer has a thickness of between 150 to 300 nanometers;
d. the first aluminum layer has a thickness of between 10 to 30 nanometers;
e. the second aluminum layer has a thickness of between 10 to 30 nanometers; and
f. the hydrogenated amorphous carbon layer has a thickness of between 5 to 25 nanometers.

20. A membrane device comprising:
a. an aluminum layer disposed between a first amorphous carbon layer and a second amorphous carbon layer;
b. the first amorphous carbon layer has a thickness of between 1 to 25 nanometers;
c. the aluminum layer has a thickness of between 10 to 60 nanometers; and
d. the second amorphous carbon layer has a thickness of between 1 to 25 nanometers.
